(19) United States
(12) Patent Application Publication
(10) Pub. No.: US 2025/0142824 A1
(43) Pub. Date: May 1, 2025

(54) SEMICONDUCTOR DEVICES

(71) Applicant: SAMSUNG ELECTRONICS CO., LTD., Suwon-si (KR)

(72) Inventors: Yuyeon Kim, Suwon-si (KR); Siyeong Yang, Suwon-si (KR); Chaeho Kim, Suwon-si (KR); Jaeho Jung, Suwon-si (KR)

(21) Appl. No.: 18/794,943

(22) Filed: Aug. 5, 2024

(30) Foreign Application Priority Data
Oct. 26, 2023 (KR) 10-2023-0144473

(51) Int. Cl. H10B 43/27

(52) U.S. Cl. CPC H10B 43/27

(57) ABSTRACT

A semiconductor device includes gate electrodes on a substrate, the gate electrodes being spaced apart from each other in a vertical direction substantially perpendicular to an upper surface of the substrate; and a memory channel structure extending through the gate electrodes in the vertical direction on the substrate. The memory channel structure may include a filling pattern extending in the vertical direction; a channel structure on a sidewall of the filling pattern and an edge portion of an upper surface of the filling pattern; a capping pattern on a central portion of the upper surface of the filling pattern and an upper surface of the channel structure; and a charge storage structure on an outer sidewall of the channel structure and a sidewall of the capping pattern.

### CROSS-REFERENCE TO RELATED APPLICATION(S)

This application claims priority to Korean Patent Application No. 10-2023-0144473, filed in the Korean Intellectual Property Office (KIPO) on Oct. 26, 2023, the contents of which are herein incorporated by reference in their entirety.

### BACKGROUND

As a semiconductor device having a high-capacity data storage is needed, the number of gate electrodes increases. Accordingly, length of the channel may become longer and while thickness of the channel may become thinner, which may deteriorate the electrical characteristics of the channel.

### SUMMARY

In general, in some aspects, the present disclosure is directed toward A semiconductor device that includes gate electrodes on a substrate, the gate electrodes being spaced apart from each other in a vertical direction substantially perpendicular to an upper surface of the substrate; and a memory channel structure extending through the gate electrodes in the vertical direction on the substrate. The memory channel structure may include a filling pattern extending in the vertical direction; a channel structure on a sidewall of the filling pattern and an edge portion of an upper surface of the filling pattern, the channel structure having a single crystalline silicon or a quasi-single crystalline silicon; a capping pattern on a central portion of the upper surface of the filling pattern and an upper surface of the channel structure, the capping pattern having polycrystalline silicon; and a charge storage structure on an outer sidewall of the channel structure and a sidewall of the capping pattern.

According to some implementations, the present disclosure is directed to a semiconductor device that includes gate electrodes on a substrate, the gate electrodes being spaced apart from each other in a vertical direction substantially perpendicular to an upper surface of the substrate; and a memory channel structure extending through the gate electrodes in the vertical direction on the substrate. The memory channel structure may include a filling pattern extending in the vertical direction; a channel structure having a first channel covering a sidewall of the filling pattern, the first channel containing a single crystalline silicon or a quasi-single crystalline silicon and a second channel on and contacting the first channel, the second channel having a shape of a ring covering an edge portion of an upper surface of the filling pattern, and the second channel containing a metal silicide; and a charge storage structure on a sidewall of the channel structure.

According to some implementations, the present disclosure is directed to a semiconductor device that includes gate electrodes on a substrate, the gate electrodes being spaced apart from each other in a vertical direction substantially perpendicular to an upper surface of the substrate; and a memory channel structure extending through the gate electrodes in the vertical direction on the substrate. The memory channel structure may include a filling pattern extending in the vertical direction; a channel structure having a first channel covering a lower surface of the filling pattern, the first channel containing polycrystalline silicon, a second channel on the first channel, the second channel covering a sidewall of the filling pattern, and the first channel containing a single crystalline silicon or a quasi-single crystalline silicon and a third channel on the second channel, the third channel covering an edge portion of an upper surface of the filling pattern, and the third channel containing a metal silicide; and a charge storage structure on a sidewall of the channel structure.

According to some implementations, the present disclosure is directed to a method of manufacturing a semiconductor device, in which the channel may be crystallized to the bottom, and electrical characteristics of the semiconductor device may be improved.

### BRIEF DESCRIPTION OF THE DRAWINGS

Example implementations will be more clearly understood from the following detailed description, taken in conjunction with the accompanying drawings.

FIG. 1 is a cross-sectional view illustrating an example of a semiconductor device in accordance with some implementations.

FIGS. 2 and 15 are cross-sectional views illustrating an example of a method of manufacturing a semiconductor device in accordance with some implementations.

FIG. 16 is a cross-sectional view illustrating an example of a semiconductor device in accordance with some implementations.

FIG. 17 is a cross-sectional view illustrating an example of a semiconductor device in accordance with some implementations.

FIG. 18 is a cross-sectional view illustrating an example of a semiconductor device in accordance with some implementations.

FIG. 19 is a cross-sectional view illustrating an example of a semiconductor device in accordance with some implementations.

FIGS. 20 to 21 are cross-sectional views illustrating an example of a method of manufacturing a semiconductor device in accordance with some implementations.

### DETAILED DESCRIPTION

Hereinafter, example implementations will be explained in detail with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of the present disclosure.

Hereinafter, in the present disclosure, a direction substantially perpendicular to upper surfaces of each first and second substrates 100 and 700 may be defined as a first direction D1, and two directions substantially parallel to the upper surfaces of each first and second substrates 100 and 700 and crossing each other may be defined as second and third directions D2 and D3, respectively. In some implementations, the second and third directions D2 and D3 may be substantially perpendicular to each other. Each of the first to third directions D1, D2 and D3 may represent not only a direction shown in the drawing, but also a reverse direction to the direction.

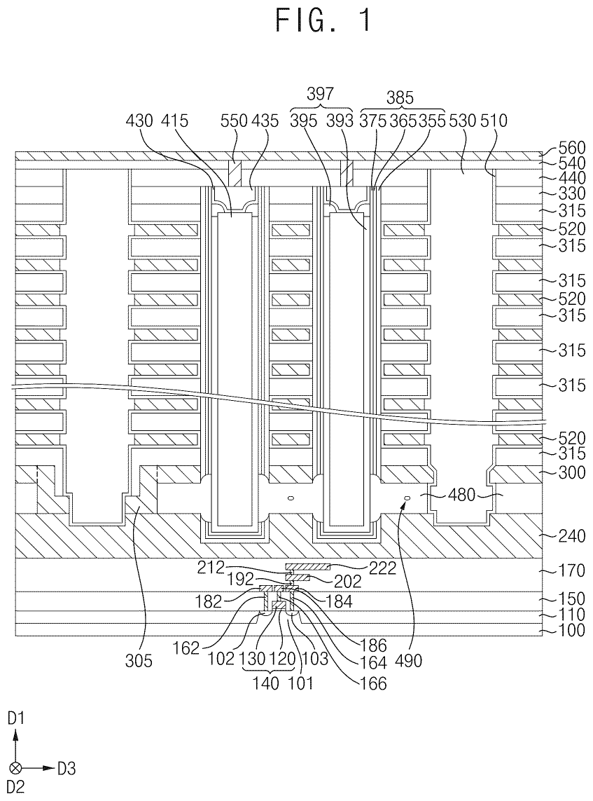

FIG. 1 is a cross-sectional view illustrating an example of a semiconductor device in accordance with some implementations. In FIG. 1, the semiconductor device may include a lower circuit pattern, a common source plate (CSP), a gate electrode structure, a memory channel structure, a division pattern 530, a contact plug 550 and a first wiring 560 on a first substrate 100.

The semiconductor device may further include a support layer 300, a support pattern 305, a channel connection pattern 480, a second blocking pattern 510, insulating patterns 315, and first to fifth insulating interlayers 150, 170, 330, 440 and 540.

The first substrate 100 may include silicon, germanium, silicon-germanium or a III-V group compound such as GaP, GaAs, GaSb, etc. In some implementations, the first substrate 100 may be a silicon-on-insulator (SOI) substrate or a germanium-on-insulator (GOI) substrate.

The first substrate 100 may include a field region on which a first isolation pattern 110 is formed and a first active region 101 on which no first isolation pattern is formed. The first isolation pattern 110 may include an oxide, e.g., silicon oxide.

In some implementations, the semiconductor device may have a cell over periphery (COP) structure. That is, the lower circuit pattern may be formed on the first substrate 100, and memory cells, contact plugs and wirings may be formed over the lower circuit pattern. The lower circuit pattern may include, e.g., transistors, lower contact plugs, lower wirings, lower vias, etc.

The transistor may include a lower gate structure 140 on the first substrate 100 and first and second impurity regions 102 and 103 at upper portions of the first active region 101 adjacent to the lower gate structure 140 serving as source/drain regions. The lower gate structure 140 may include a lower gate insulation pattern 120 and a lower gate electrode 130 sequentially stacked on the first substrate 100.

The first insulating interlayer 150 may be formed on the first substrate 100 to cover the transistors, and first and second lower contact plugs 162 and 164 extending through the first insulating interlayer 150 to contact the first and second impurity regions 102 and 103, respectively, and a third lower contact plug 166 extending in the first insulating interlayer 150 to contact the lower gate electrode 130 may be formed.

First to third lower wirings 182, 184 and 186 may be formed on the first insulating interlayer 150 to contact upper surfaces of the first to third lower contact plugs 162, 164 and 166, respectively. A first lower via 192, a fourth lower wiring 202, a second lower via 212 and a fifth lower wiring 222 may be sequentially stacked on the lower wiring 184.

The second insulating interlayer 170 may be formed on the first insulating interlayer 150 to cover the first to fifth lower wirings 182, 184, 186, 202 and 222 and the first and second lower vias 192 and 212. In some implementations, the second insulating interlayer 170 may be merged with the first insulating interlayer 150.

The CSP 240 may be formed on the second insulating interlayer 170. The CSP 240 may include, e.g., polysilicon doped with n-type impurities. In some implementations, the CSP 240 may include a metal silicide layer and a doped polysilicon layer sequentially stacked. The metal silicide layer may include, e.g., tungsten silicide.

The channel connection pattern 480 may be formed on the CSP 240, and the support layer 300 may be formed on the channel connection pattern 480. Referring to FIG. 3 together with FIG. 1, the support layer 300 may also be formed in the first opening 302 that extends through the channel connection pattern 480 and exposes an upper surface of the CSP 240, and a portion of the support layer 300 within the first opening 302 may be referred to as the support pattern 305. The channel connection pattern 480 may include an air gap 515 therein.

Each of the channel connection pattern 480, the support layer 300 and the support pattern 305 may include, for example, polysilicon doped with n-type impurities or undoped polysilicon.

The gate electrode structure may include a plurality of gate electrodes 520 respectively formed in a plurality of levels spaced apart from each other in the first direction D1 on the support layer 300 and the support pattern 305. Each of the insulating patterns 315 may be formed between the gate electrodes 520 and between the gate electrode 520 and the support layer 300 and the support pattern 305. The insulating pattern 315 may include, for example, an oxide, such as silicon oxide.

In some implementations, the gate electrode structure may include first to third gate electrodes sequentially stacked in the first direction D1. In some implementations, the first gate electrode may be formed at a lowermost level, and may serve as a ground selection line (GSL). The third gate electrode may be formed at an uppermost level and a second level from above, and may serve as a string selection line (SSL). The second gate electrode may be formed at a plurality of levels between the first and third gate electrodes, and may serve as word lines, respectively. However, the numbers of levels at which the first to third gate electrodes are formed might not be limited to the above, and may be varied. Additionally, each of the gate electrode structures may include fourth gate electrode under the first gate electrode and/or over the third gate electrode. The fourth gate electrode may be formed at one or a plurality of levels, and may serve as a gate induced drain leakage (GIDL) electrode, which may use GIDL phenomenon to enable body erase. Some of the second gate electrodes may serve as dummy word lines.

The third to fifth insulating interlayer 330, 440 and 540 may be sequentially stacked in the first direction D1 on an uppermost one of the insulating patterns 315. Each of the third to fifth insulating interlayers 330, 440 and 540 may include, for example, an oxide such as silicon oxide.

The division pattern 530 may extend in the second direction D2 through the gate electrode structure and the third and fourth interlayer insulating layers 330 and 440. The division pattern 530 may include, for example, an oxide such as silicon oxide.

The memory channel structure may contact an upper surface of the CSP 240 and may extend through the channel connection pattern 480, the gate electrode structure, the insulating pattern 315 and the third insulating interlayer 330. In some implementations, the memory channel structure may include a filling pattern 415 that extends in the first direction D1 and has a pillar shape, a channel structure 397 on a sidewall, a lower surface, and an edge portion of an upper surface of the filling pattern 415, a seed pattern 430 on an upper surface of the filling pattern 415, an upper surface of the channel structure 397 and an inner sidewall of the charge storage structure, and a capping pattern 435 in which a sidewall and a lower surface thereof are covered by the seed pattern 430, and the charge storage structure 385 on an outer sidewall of the channel structure 397 and an outer sidewall of the seed pattern 430.

In some implementations, a plurality of memory channel structures may be spaced apart from each other in the second and third directions D2 and D3, and a plurality of memory channel structures may be connected to each other by the channel connection pattern 480. Specifically, the charge storage structure 385 may not be formed a portion of the outer sidewall of the channel structures 397, and the channel connection pattern 480 may contact the portion of the outer sidewalls of the channel structures 397 so as to electrically connect the channel structures 397 to each other.

The filling pattern 415 may include, for example, an oxide such as silicon oxide, the seed pattern 430 may include, for example, polysilicon doped with oxygen (O), carbon (C), nitrogen (N), etc., and the capping pattern 435 may include, for example, polysilicon doped with n-type impurities, such as phosphorus (P), arsenic (As), etc.

The channel structure 397 may include a first channel 393 on the sidewall and the lower surface of the filling pattern 415 and having a shape of, for example, a cup, and a second channel 395 on an upper surface of the first channel 393 and the edge portion of the upper surface of the filling pattern 415. In some implementations, an outer sidewall of the first channel 393 and an outer sidewall of the second channel 395 may be aligned with each other in the first direction D1.

In some implementations, the upper surface of the first channel 393 may be lower than the upper surface of the filling pattern 415, and accordingly, a lower portion of the second channel 395 on the first channel 393 may contact an uppermost portion of a sidewall of the filling pattern 415. Hereinafter, a portion of the second channel 395 lower than the upper surface of the filling pattern 415 may be referred to as a first portion, and a portion of the second channel 395 higher than the upper surface of the filling pattern 415 may be referred to as a second portion.

In some implementations, in a top view, the second channel 395 may have a shape of a ring surrounding an edge portion of the filling pattern 415, and each of the first and second portions of the second channel 395 may also have a shape of a ring.

In some implementations, an inner diameter of the first channel 393 and a first inner diameter of the first portion of the second channel 395 may be substantially the same, and an inner sidewall of the first channel 393 and an inner sidewall of the first portion of the second channel 393 may be aligned with each other in the first direction D1. A first outer diameter of the first portion of the second channel 395 and a second outer diameter of the second portion of the second channel 395 may be substantially the same, while the first inner diameter of the first portion of the second channel 395 may be greater than a second inner diameter of the second portion of the second channel 395. In some implementations, the second inner diameter of the second portion of the second channel 395 may gradually increase in the first direction D1 away from the upper surface of the first substrate 100.

In some implementations, the second channel 395 may include a silicide of a metal such as nickel (Ni), cobalt (Co), platinum (Pt), etc. An upper portion of the first channel 393 may also include the metal.

In some implementations, each of the first and second channels 393 and 395 may include an element that delays thermal crystallization (Solid Phase Crystallization: SPC such as oxygen (O), carbon (C), nitrogen (N), etc.

In some implementations, the channel structure 397 may include a single crystalline silicon or a quasi-single crystalline silicon, and in particular, a lowermost portion in the first direction D1 of the channel structure 397 may be a single crystalline silicon or a quasi-single crystalline silicon. In comparison, each of the seed pattern 430 and the capping pattern 435 may include polycrystalline silicon, that is, polysilicon. Accordingly, silicon of the channel structure 397 may have a larger crystal size than that of silicon of the capping pattern 435.

In some implementations, silicon crystals of the channel structure 397 may have a substantially constant orientation. In comparison, silicon crystals of the seed pattern 430 and the capping pattern 435 may have random orientation.

The charge storage structure 385 may a tunnel insulation pattern 375, a charge storage pattern 365 and a first blocking pattern 355 sequentially stacked in the horizontal direction at the outer sidewall of the channel structure 397 and the outer sidewall of the seed pattern 430.

The tunnel insulation pattern 375 may include, for example, an oxide such as silicon oxide, and the charge storage pattern 365 may include, for example, a nitride, such as silicon nitride and the first blocking pattern 355 may include, for example, an oxide, such as silicon oxide.

The second blocking pattern 510 may cover upper and lower surfaces and sidewalls facing the memory channel structure of each of the gate electrodes 520. The second blocking pattern 510 may include, for example, a metal oxide, such as aluminum oxide, hafnium oxide etc.

The contact plug 550 may extend through the fourth and fifth insulating interlayers 440 and 540 to contact the upper surface of the capping pattern 435.

The first wiring 560 may be formed on the fifth insulating interlayer 540 and extend in the third direction D3, and a plurality of first wirings 560 may be spaced apart from each other in the second direction D2 to serve as a bit line of the semiconductor device. In some implementations, an additional upper wiring that may serve as a bit line may be formed on the first wiring 560.

As described below, the channel structure 397 of the semiconductor device may be formed to include a single crystalline silicon or a quasi-single crystalline silicon up to the bottom. Accordingly, the semiconductor device including the channel structure 397 may have improved electrically characteristics.

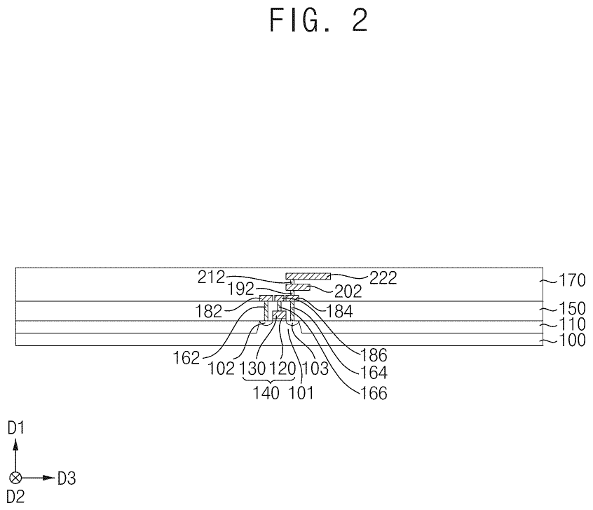

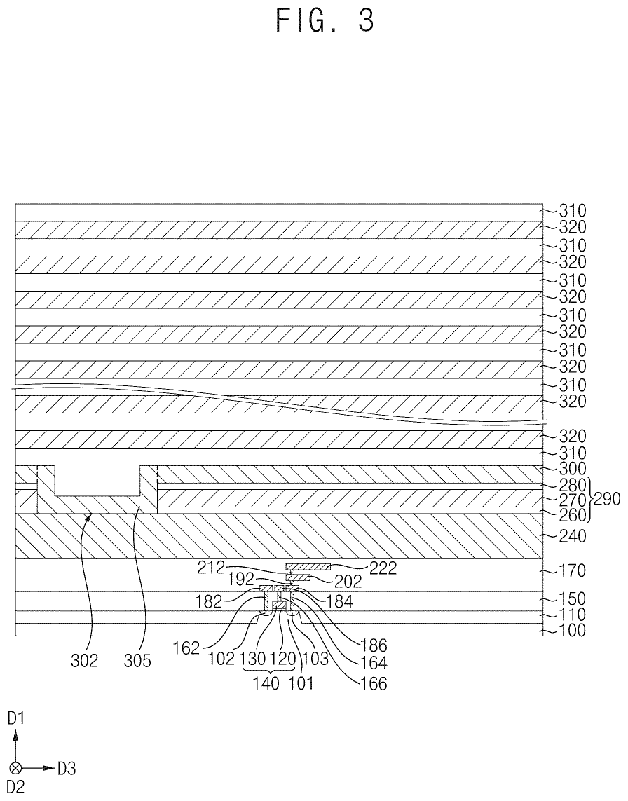

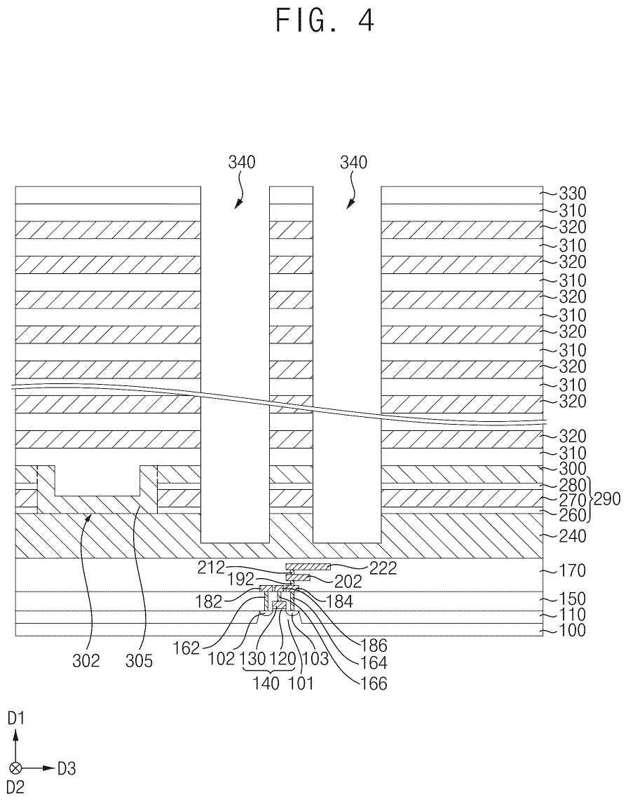

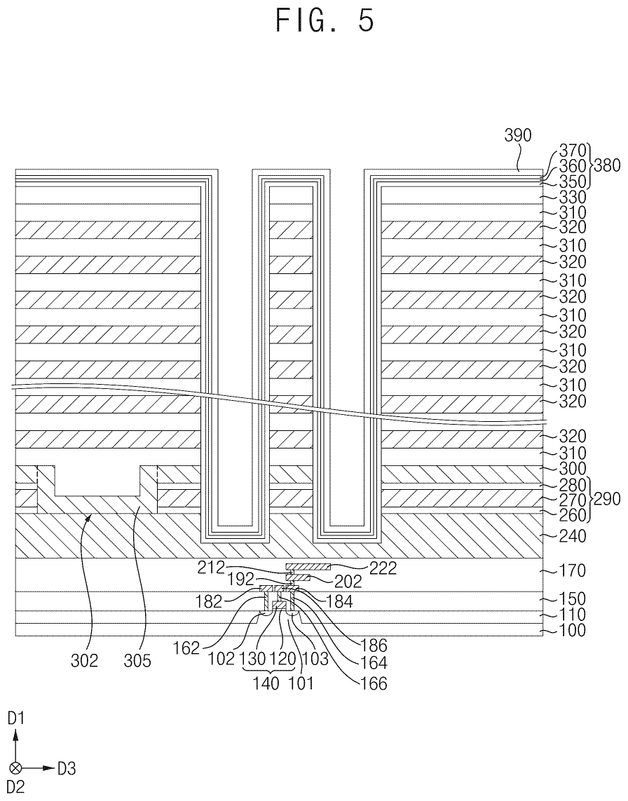

FIGS. 2 to 15 are cross-sectional views illustrating an example of a method of manufacturing a semiconductor device in accordance with some implementations. In FIG. 2, a lower circuit pattern may be formed on the first substrate 100. The first substrate 100 may include a field region on which a first isolation pattern 110 is formed and a first active region 101 on which no first isolation pattern is formed. The lower circuit pattern may include, e.g., transistors, lower contact plugs, lower wirings, lower vias, etc.

The transistor may include a lower gate structure 140 on the first substrate 100 and first and second impurity regions 102 and 103 at upper portions of the first active region 101 adjacent to the lower gate structure 140 serving as source/drain regions. The lower gate structure 140 may include a lower gate insulation pattern 120 and a lower gate electrode 130 sequentially stacked on the first substrate 100.

The first insulating interlayer 150 may be formed on the first substrate 100 to cover the transistors, and first and second lower contact plugs 162 and 164 extending through the first insulating interlayer 150 to contact the first and second impurity regions 102 and 103, respectively, and a third lower contact plug 166 extending in the first insulating interlayer 150 to contact the lower gate electrode 130 may be formed.

First to third lower wirings 182, 184 and 186 may be formed on the first insulating interlayer 150 to contact upper surfaces of the first to third lower contact plugs 162, 164 and 166, respectively. A first lower via 192, a fourth lower wiring 202, a second lower via 212 and a fifth lower wiring 222 may be sequentially stacked on the lower wiring 184.

The second insulating interlayer 170 may be formed on the first insulating interlayer 150 to cover the first to fifth lower wirings 182, 184, 186, 202, and 222 and the first and second lower vias 192 and 212. In some implementations, the second insulating interlayer 170 may be merged with the first insulating interlayer 150.

Each element included in the lower circuit pattern may be formed by, e.g., a damascene process or a patterning process.

In FIG. 3, a common source plate (CSP) 240 and a sacrificial layer structure 290 may be sequentially formed on the second insulating interlayer 170, the sacrificial layer structure 290 may be partially removed to form a first opening 302 exposing an upper surface of the CSP 240 and a support layer 300 may be formed on an upper surface of the sacrificial layer structure 290 and the exposed upper surface of the CSP 240.

The sacrificial layer structure 290 may include first, second and third sacrificial layers 260, 270, and 280 sequentially stacked. The first and third sacrificial layers 260 and 280 may include an oxide, e.g., silicon oxide, and the second sacrificial layer 270 may include a nitride, e.g., silicon nitride.

The support layer 300 may include a material having an etching selectivity with respect to the first to third sacrificial layers 260, 270, and 280, e.g., polysilicon doped with n-type impurities. The support layer 300 may have a uniform thickness, and thus a first recess may be formed on a portion of the support layer 300 in the first opening 302. Hereinafter, the portion of the support layer 300 in the first opening 302 may be referred to as a support pattern 305.

An insulation layer 310 and a fourth sacrificial layer 320 may be alternately and repeatedly stacked on the support layer 300 and the support pattern 305, and a mold layer including the insulation layers 310 and the fourth sacrificial layers 320 alternately stacked may be formed. The insulation layer 310 may include an oxide, e.g., silicon oxide, and the fourth sacrificial layer 320 may include a material having an etching selectivity with respect to the insulation layer 310, e.g., a nitride such as silicon nitride.

In FIG. 4, a third insulating interlayer 330 may be formed on the first substrate 100 to cover the mold, and a dry etching process may be performed to form a channel hole 340 extending in the first direction D1 through the third insulating interlayer 330 and the mold and exposing an upper surface of the CSP 240.

In some implementations, the dry etching process may be performed until the channel hole 340 may expose the upper surface of the CSP 240, and further the channel hole 340 may extend through an upper portion of the CSP 240. In some implementations, a plurality of channel holes 340 may be spaced apart from each other in the second and third directions D2 and D3.

In FIG. 5, a charge storage layer structure 380 and a channel layer 390 may be sequentially formed on a sidewall of the channel hole 340, the exposed upper surface of the CSP 240 and the third insulating interlayer 330. The charge storage layer structure 380 may include a first blocking layer 350, a charge storage layer 360 and a tunnel insulation layer 370 sequentially stacked.

The channel layer 390 may be formed by a deposition process, for example, a chemical vapor deposition (CVD) process or an atomic layer deposition (ALD) process, and may be formed to include, for example, amorphous silicon.

The deposition process may be performed by using a silicon source gas. In some implementations, the deposition process may be performed by using together a source gas of oxygen (O), carbon (C), nitrogen (N), etc. to delay thermal crystallization (Solid Phase Crystallization: SPC) of amorphous silicon of the channel layer 390.

In FIG. 6, a filling layer 410 may be formed on the channel layer 390 to fill the channel hole 340. A filling pattern 415 may be formed by removing an upper portion of the filling layer 410 by, for example, performing an etch-back process.

In FIG. 7, an upper portion of the channel layer 390 on the charge storage structure layer 380 may be removed by performing an etching process. Accordingly, the channel layer 390 may be transformed into a plurality of first preliminary channels 393a spaced apart from each other in the second and third directions D2 and D3. In some implementations, an upper surface of each of the first preliminary channels 393a may be lower than an upper surface of the filling pattern 415.

In FIG. 8, a selective deposition process may be performed to form a second preliminary channel 395a on the upper surface of the first preliminary channel 393a including silicon. The second preliminary channel 395a may also be formed on the upper surface of a portion of the filling pattern 415 adjacent to the second preliminary channel 395a, that is, the upper surface of an edge portion of the filling pattern 415. The second preliminary channel 395a may include, for example, amorphous silicon. An upper surface of the second preliminary channel 395a may be formed to have a larger area than the upper surface of the first preliminary channel 393a.

In some implementations, the selective deposition process may be performed, for example, by a chemical vapor deposition (CVD) process or an atomic layer deposition (ALD) process. The selective deposition process may be performed by using a silicon source gas. In some implementations, the selective deposition process may be performed by using together a source gas of oxygen (O), carbon (C), nitrogen (N), etc.

A metal layer may be formed on the second preliminary channel 395a, the filling pattern 415 and the charge storage structure layer 380 and a heat treatment process may be performed thereon, and thus the second preliminary channel 395a may react with the metal layer to generate metal silicide. After the heat treatment process, a portion of the metal layer that has not reacted with the second preliminary channel 395a may be removed.

In FIG. 9, a crystallization process may be performed on the first and second preliminary channels 393a and 395a to crystallize the amorphous silicon thereof, thereby converting the first and second preliminary channels 393 and 395a, respectively, into the first and second channels 393 and 395. The first and second channels may together form the channel structure 397.

In some implementations, the crystallization process may be a Metal Induced Lateral Crystallization (MILC) process. The MILC process may be performed at about 500 to 800° C., and as the MILC process is performed, amorphous silicon of the second preliminary channel 395a and the first preliminary channel 393a thereunder, may be converted into a single crystalline silicon or a quasi-single crystalline silicon by the metal silicide of the second preliminary channel 395a.

The upper surface of the second preliminary channel 395a may have a greater area than that of the upper surface of the first preliminary channel 393a, and accordingly, the MILC process may be prevented from being bothered by structures adjacent to the first preliminary channel 393a, for example, the filling pattern 415, the charge storage structure layer 380, etc., and may be performed smoothly. Accordingly, even if the first preliminary channel 393a has a relatively great length in the first direction D1, a lower portion of the first preliminary channel 393a may be fully converted into the first channel 393 to have a single crystalline silicon or a quasi-single crystalline silicon.

Each of the first and second preliminary channels 393a and 395a may further include elements such as oxygen (O), carbon (C), nitrogen (N), etc. Accordingly, crystallization by MILC may be mainly performed and crystallization by SPC may be delayed. Accordingly, each of the first and second channels 393 and 395 may be formed to include silicon crystals of a relatively large sizes compared to silicon crystals generated by pure heat treatment.

During the MILC process, some of the metal of the second preliminary channel 395a may move to the first preliminary channel 393a, and accordingly, not only the second channel 395 but also an upper portion of the first channel 393 may include the metal.

In FIG. 10, a seed layer may be formed on the channel structure 397, the filling pattern 415 and the charge storage structure layer 380, a capping layer may be formed on the seed layer to a sufficient height, and the capping layer, the seed layer and the charge storage layer structure 380 may be planarized until an upper surface of the third insulating interlayer 330 is exposed, and thus, a capping pattern 435, a seed pattern 430, and a charge storage structure 385 may be formed in the channel hole 340.

The seed layer may include, for example, polysilicon doped with oxygen (O), carbon (C), nitrogen (N), etc. The seed layer may be formed on the channel structure 397 and the filling pattern 415, which may include different materials from each other, and accordingly, the capping layer may be substantially uniformly formed on the seed layer.

The charge storage structure 385 may include a first blocking pattern 355, a charge storage pattern 365, and a tunnel insulation pattern 375 sequentially stacked on a sidewall and a bottom of the channel hole 340.

The channel holes 340 in which the channel structures 397 are respectively formed may define a channel hole array. Accordingly, the channel structures 397 respectively formed in the channel holes 340 may also form a channel array.

The charge storage structure 385, the channel structure 397, the filling pattern 415 and the capping pattern 435 may together form a memory channel structure.

In FIG. 11, a fourth insulating interlayer 440 may be formed on the third insulating interlayer 330, the capping pattern 435 and the charge storage structure 385, and a second opening 450 partially extending through the third and fourth insulating interlayers 330 and 440, and the mold may be formed by a dry etching process.

In some implementations, the dry etching process my be performed until the second opening 450 exposes an upper surface of the support layer 300 or the support pattern 305, and further, the second opening 450 may extend through an upper portion of the support layer 300 or the support pattern 305. As the second opening 450 is formed, the insulation layer 310 and the fourth sacrificial layer 320 included in the mold may be exposed.

In some implementations, the second opening 450 may extend in the second direction D2, and a plurality of second openings 450 may be formed in the third direction D3. As the second opening 450 is formed, the insulation layer 310 may be divided into insulation patterns 315 each of which may extend in the second direction D2, and the fourth sacrificial layer 320 may be divided into fourth sacrificial patterns 325 each of which may extend in the second direction D2.

A spacer layer may be formed on a sidewall of the second opening 450, the upper surfaces of the support layer 300 and the support pattern 305 exposed by the second opening 450, and the fourth insulating interlayer 440, and may be anisotropically etched so that portions of the spacer layer on the support layer 300 and the support pattern 305 may be removed to form a spacer 460, and the upper surfaces of the support layer 300 and the support pattern 305 may be partially exposed.

In some implementations, the spacer 460 may include, e.g., undoped amorphous silicon or undoped polysilicon.

The exposed portions of the support layer 300 and the support pattern 305 and a portion of the sacrificial layer structure 290 thereunder may be removed to enlarge the second opening 450. Accordingly, the second opening 450 may expose an upper surface of the CSP 240, and further, may extend through an upper portion of the CSP 240.

When the sacrificial layer structure 290 is partially removed, a sidewall of the second opening 450 may be covered by the spacer 460, and the spacer 460 may include a material different from the sacrificial layer structure 290, and the insulation pattern 315 and the fourth sacrificial pattern 325 included in the mold might not be removed.

In FIG. 12, the sacrificial layer structure 290 exposed by the second opening 450 may be removed to form a first gap 470 exposing a lower outer sidewall of the charge storage structure 385, and further, a portion of the charge storage structure 385 exposed by the first gap 470 may be removed to expose a lower outer sidewall of the channel 395.

The sacrificial layer structure 290 and the charge storage structure 385 may be removed by a wet etching process, using e.g., fluoric acid and/or phosphoric acid. When the first gap 470 is formed, the support layer 300, the support pattern 305, the channel structure 397, and the filling pattern 415 might not be removed and support the mold.

As the first gap 470 is formed, the charge storage structure 385 may be divided into an upper portion extending through the mold to cover most portion of the outer sidewall of the channel structure 397 and a lower portion covering a lower surface of the channel structure 397 on the CSP 240.

In FIG. 13, after removing the spacer 460, a channel connection pattern 480 may be formed to fill the first gap 470.

The channel connection pattern 480 may be formed by forming a channel connection layer on the sidewall of the second opening 450, the exposed upper surface of the CSP 240, and the fourth insulating interlayer 440, and performing an etch back process on the channel connection layer. As the channel connection pattern 480 is formed, the channel structures 397 between neighboring ones of the second openings 450 in the third direction D3 may be connected with each other to form a channel block.

An air gap 490 may be formed in the channel connection pattern 480.

In FIG. 14, the fourth sacrificial patterns 325 may be removed to form a second gap 500 exposing an outer sidewall of the charge storage structure 385.

The fourth sacrificial patterns 325 may be removed by a wet etching process, using e.g., phosphoric acid (H₃PO₄) or sulfuric acid (H₂SO₄).

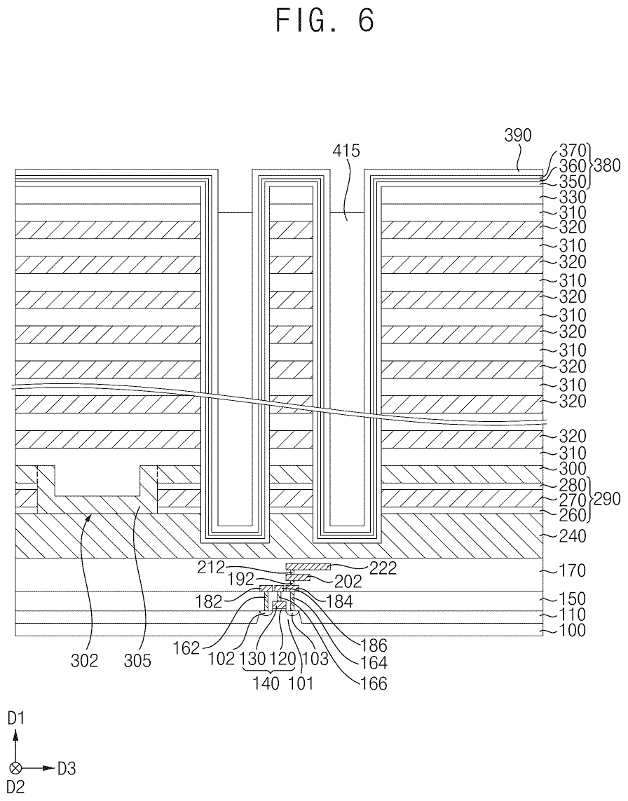

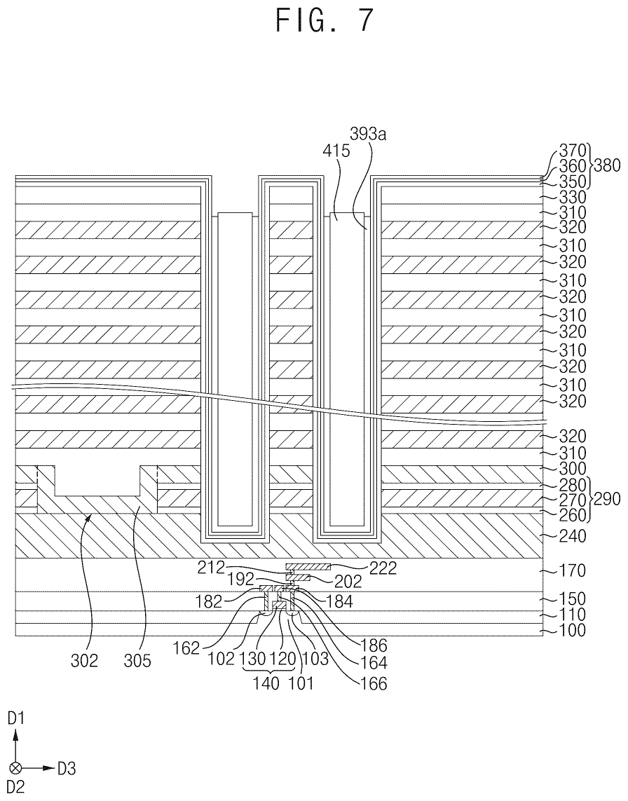

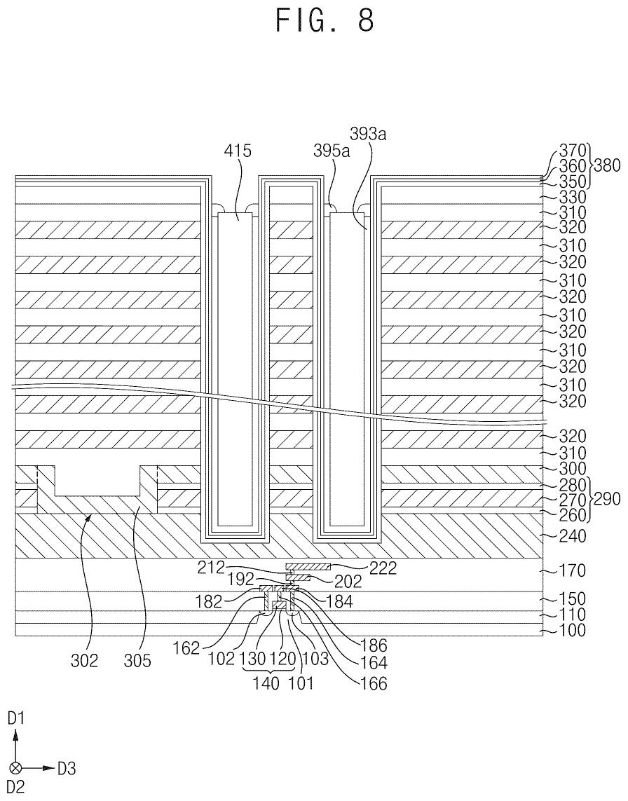

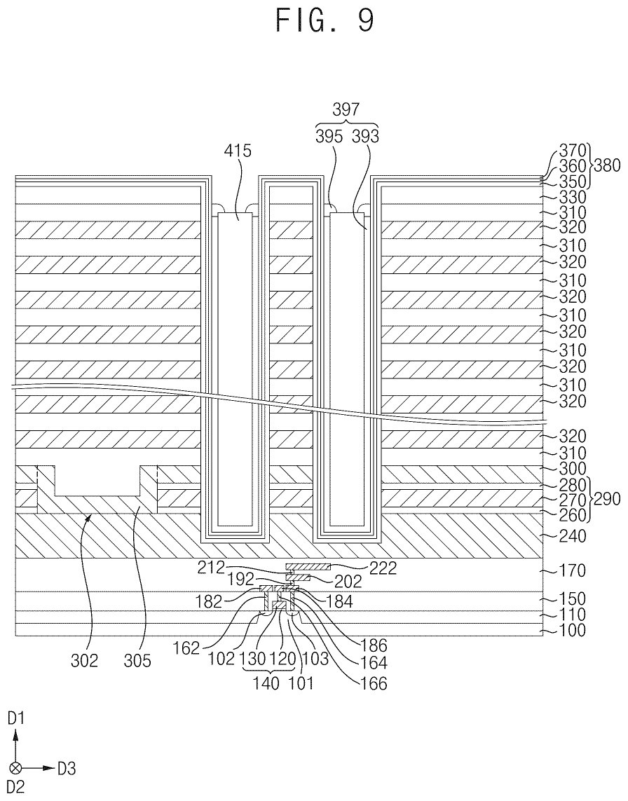

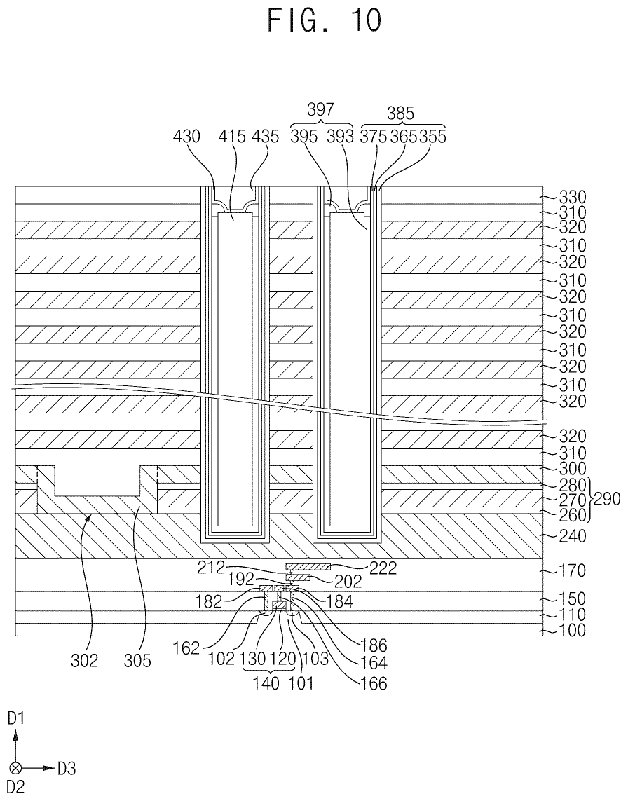

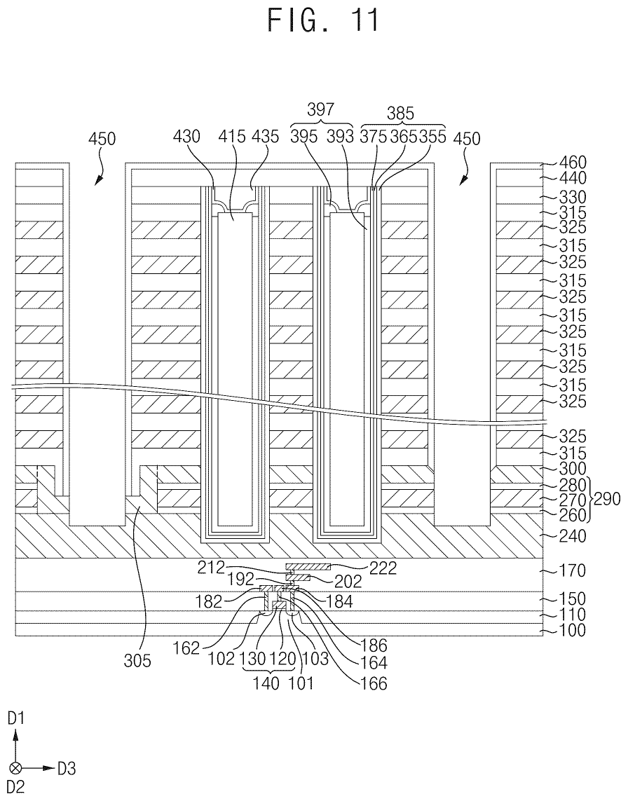

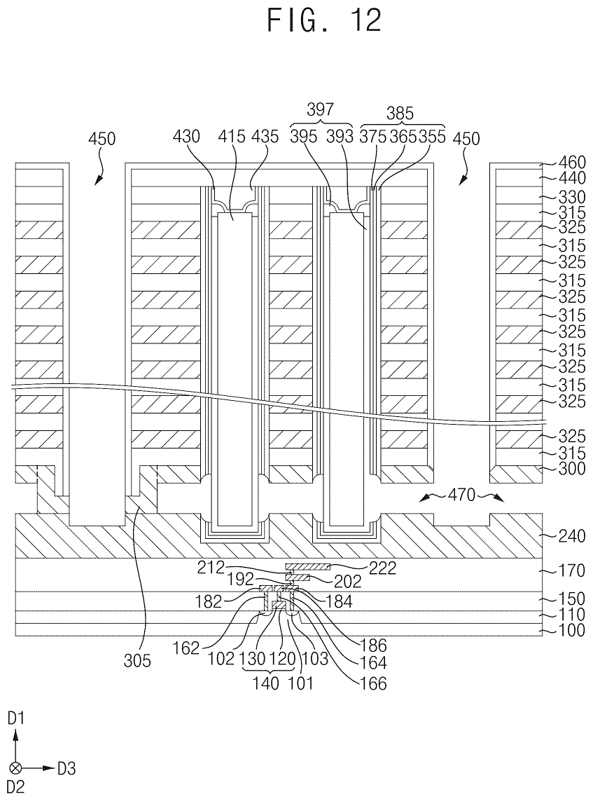

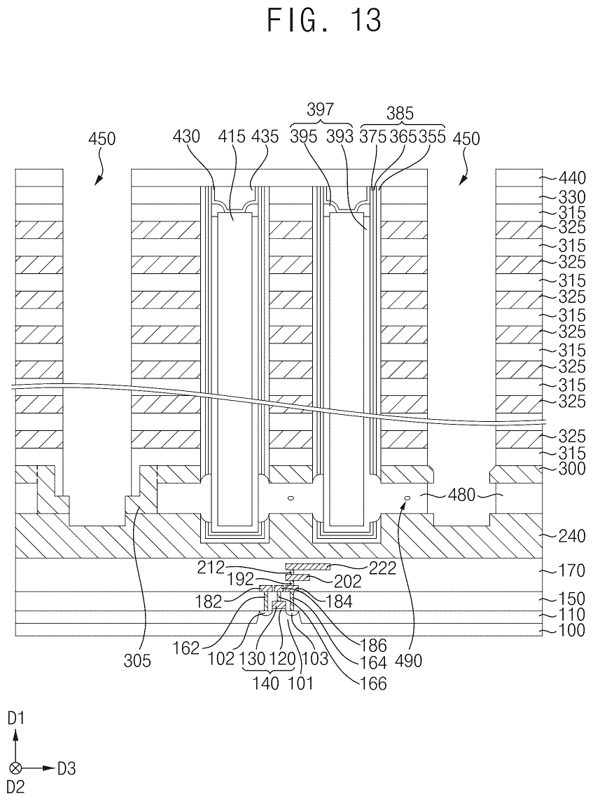

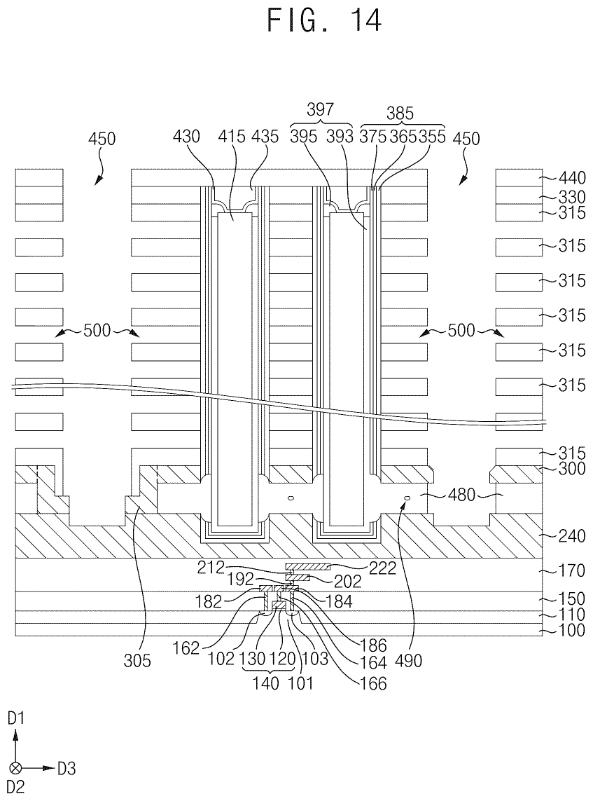

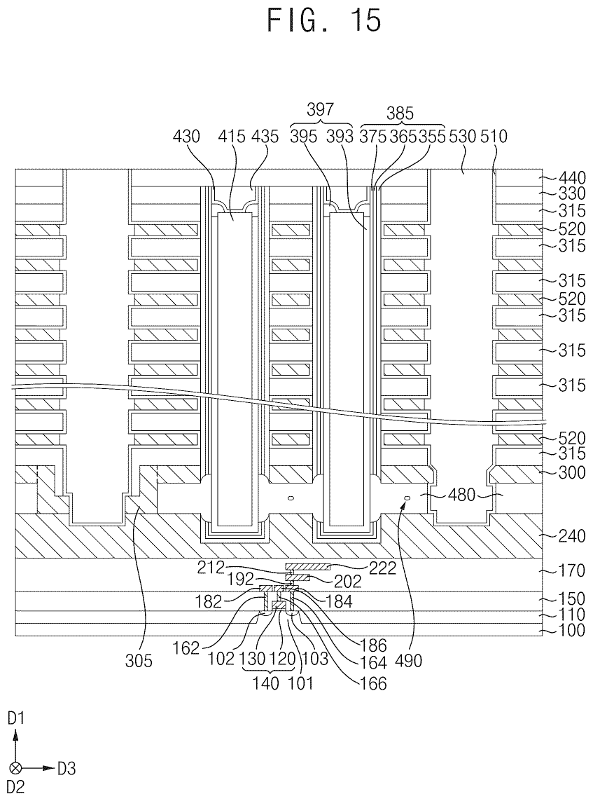

In FIG. 15, a second blocking layer may be formed on the outer sidewalls of the charge storage structures 385 exposed by the second gaps 500, inner walls of the second gaps 500, surfaces of the insulation patterns 315, sidewalls of the support layer 300 and the support pattern 305, a sidewall of the channel connection pattern 480, the upper surface of the CSP 240, and an upper surface of the fourth insulating interlayer 440, and a gate electrode layer may be formed on the second blocking layer to fill the second gaps 500 and the second opening 450. The gate electrode layer may include a gate barrier layer and a gate conductive layer sequentially stacked.

The gate electrode layer may be partially removed to form a gate electrode 520 in each of the second gaps 500. In some implementations, the gate electrode layer may be partially removed by a wet etching process.

In some implementations, the gate electrode 520 may extend in the second direction D2, and a plurality of gate electrodes 520 may be spaced apart from each other in the first direction D1 to form a gate electrode structure. Additionally, a plurality of gate electrode structures may be spaced apart from each other in the third direction D3 by the second opening 450.

A division layer may be formed on the second blocking layer to fill the second opening 450, and the division layer and the second blocking layer may be planarized until the upper surface of the fourth insulating interlayer 440 is exposed. Accordingly, the second blocking layer may be transformed into a second blocking pattern 510, and the division layer may be transformed into a division pattern 530 extending in the second direction D2 in the second opening 450.

In FIG. 1, a fifth insulating interlayer 540 may be formed on the fourth insulating interlayer 440, the division pattern 530 and the second blocking pattern 510, and a contact plug 550 may extending through the fourth and fifth insulating interlayers 440 and 540 may be formed to contact an upper surface of the capping pattern 435.

A sixth insulating interlayer may be formed on the fifth insulating interlayer 540 and the contact plug 550, and a first wiring extending through the sixth insulating interlayer to contact an upper surface of the contact plug 550. In some implementations, the first wiring 560 may extend in the third direction D3, and a plurality of first wirings 560 may be spaced apart from each other in the second direction D2.

Upper contact plugs contacting upper surface of the gate electrodes 520, respectively, and upper wirings for applying electrical signals to the upper contact plugs may be further formed to complete the fabrication of the semiconductor device.

As described above, the first preliminary channel 393a may be formed, a second preliminary channel 395a with a greater upper surface than that of the first preliminary channel 393a and including amorphous silicon may be additionally formed on the first preliminary channel 393a, the second preliminary channel 395a may be converted to further include the metal silicide, and the MILD process may be performed by using the metal silicide of the second preliminary channel 395a so as to convert the first and second preliminary channels 393a and 395a, respectively into the first and second channels 393 and 395 including a single crystalline silicon or a quasi-single crystalline silicon.

Accordingly, the MILC process may smoothly performed without being disturbed by structures adjacent to the first preliminary channel 393a. Even if the first preliminary channel 393a has a relatively great length in the first direction D1, the first preliminary channel 393a may be converted into the first channel 393 including a single crystalline silicon or a quasi-single crystalline silicon up to the bottom.

Accordingly, the first and second channels 393 and 395 may entirely include a single crystalline silicon or a quasi-single crystalline silicon, and the semiconductor device including the first and second channels 393 and 395 may have improved electrical characteristics

FIG. 16 is a cross-sectional view illustrating an example of a semiconductor device in accordance with some implementations. The semiconductor device may be substantially the same as or similar that of FIG. 1, except for further including a third channel 396, and thus repeated explanations are omitted herein.

Even after performing the MILC process illustrated with reference to FIG. 9, amorphous silicon of the first preliminary channel 393a may not be crystallized to the bottom. Accordingly, a lower portion of the first preliminary channel 393a may be converted into the third channel 396 including polycrystalline silicon by heat accompanying subsequent process.

The third channel 396 is shown to have a shape of a cup covering a lower sidewall and a lower surface of the filling pattern 415, but the present disclosure is not limited thereto. That is, the third channel 396 may have a shape of a disk that does not cover the lower sidewall of the filling pattern 415.

FIG. 17 is a cross-sectional view illustrating an example of a semiconductor device in accordance with some implementations. The semiconductor device may be substantially the same as or similar that of FIG. 1, except for the shape of the memory channel structure, and thus repeated explanations are omitted herein.

In FIG. 17, the memory channel structure may include a lower portion and an upper portion sequentially stacked, and each of the lower portion and the upper portion may have a width that gradually decreases from top to bottom along the first direction D1. In some implementations, in each of the memory channel structures, an upper surface of the lower portion may have a greater width than that of a lower surface of the upper portion.

The memory channel structure is shown to include two portions, the lower portion and the upper portion, but the concept of the present invention is not necessarily limited thereto, and may include three or more portions. Each of the portions may have a width that gradually decreases from top to bottom, and a width of an upper surface of a portion relatively below may be greater than a width of a lower surface of a portion right above.

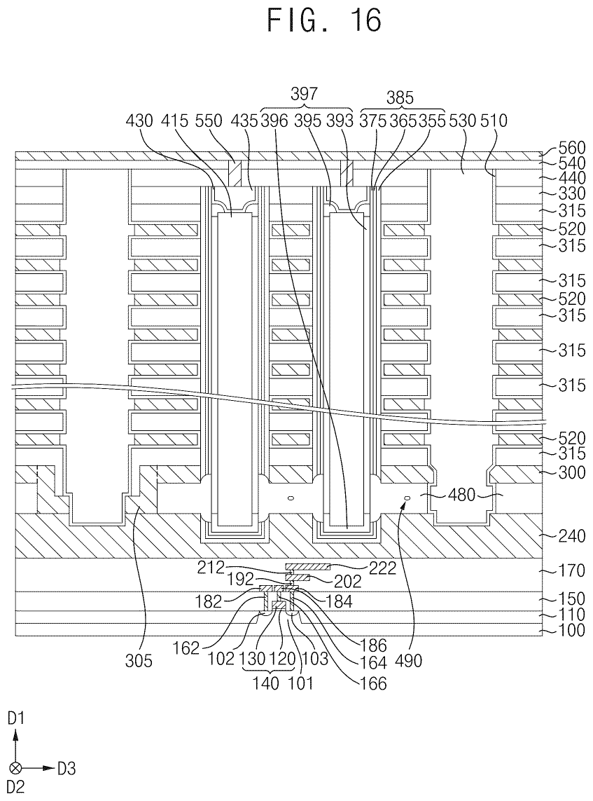

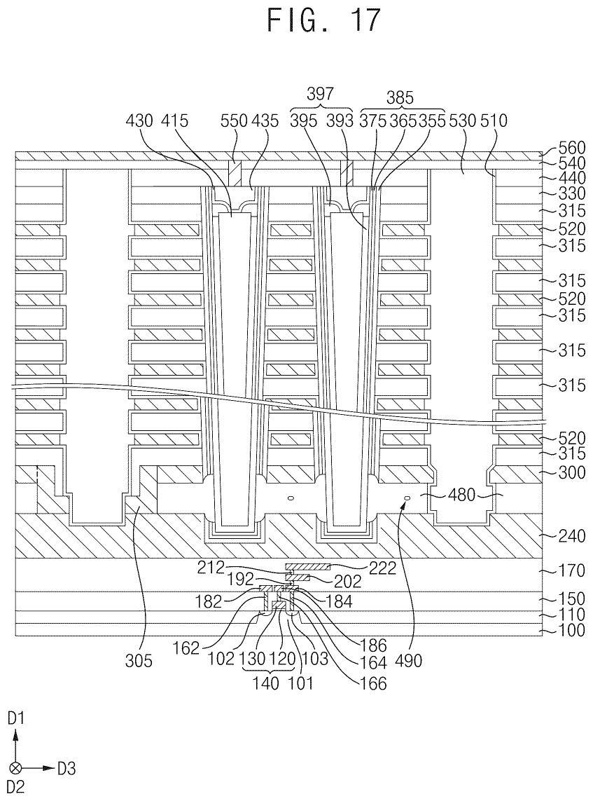

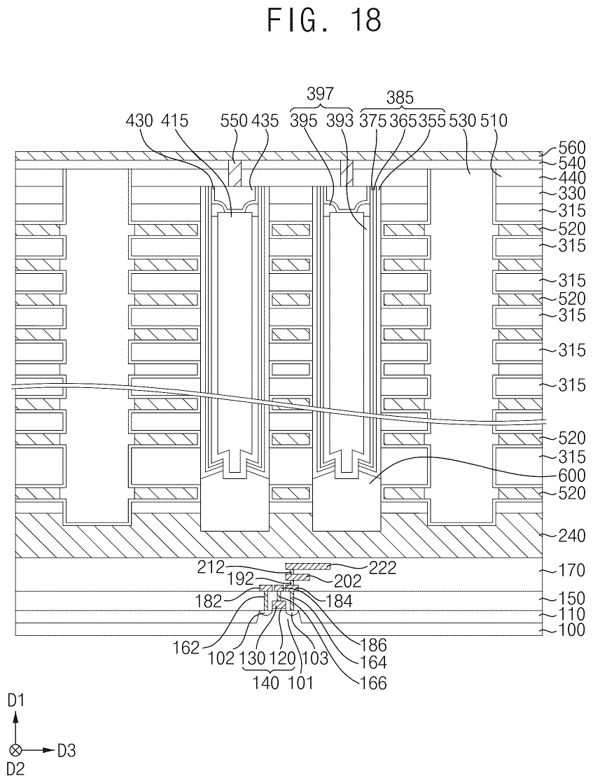

FIG. 18 is a cross-sectional view illustrating an example of a semiconductor device in accordance with some implementations. The semiconductor device may be substantially the same as or similar that of FIG. 1, except for the memory channel structure, the channel connection pattern 480, the support layer 300 and the support pattern 305, and repeated explanations are omitted herein.

In FIG. 18, the memory channel structure may further include a semiconductor pattern 600 formed on the first substrate 100, and the charge storage structure 385, the channel structure 397, the filling pattern 415 and the capping pattern 435 may be formed on the semiconductor pattern 600.

The semiconductor pattern 600 may include, for example, a single crystalline silicon or polycrystalline silicon. In some implementations, an upper surface of the semiconductor pattern 600 may be at a height between a lower surface and an upper surface of the insulating pattern 315 formed between the gate electrodes 520 at a lowermost level and a second level from below.

The charge storage structure 385 may have a shape of a cup with an opening at a center of a lower surface thereof, and may contact an edge portion of the upper surface of the semiconductor pattern 600. The channel structure 397 may have a shape of a cup on the upper surface of the semiconductor pattern 600 and may contact a center portion of the upper surface of the semiconductor pattern 600. Accordingly, the channel structure 397 may be electrically connected to the first substrate 100 through the semiconductor pattern 600.

The channel connection pattern 480, the support layer 300 and the support pattern 305 may not be formed between the first substrate 100 and a lowermost one of the gate electrodes 520. In some implementations, the insulating pattern 315 between the gate electrodes 520 formed at the lowermost level and the second level from below may have a greater thickness than the insulating patterns 315 of higher levels.

FIG. 19 is a cross-sectional view illustrating an example of a semiconductor device in accordance with some implementations. The semiconductor device may be substantially the same as or similar that of FIG. 1, except for including an upper circuit pattern instead of the lower circuit pattern and further including a via 575, a second wiring 590, and first and second bonding patterns 610 and 850 etc., and repeated explanations are omitted herein.

In FIG. 19, unlike the semiconductor device illustrated with reference to FIG. 1, the semiconductor device may have a bonding VNAND structure rather than a COP structure. That is, the semiconductor device may be formed by forming a first bulk including the first substrate 100 and the memory cells thereon, and a second bulk including a second substrate 700 and the upper circuit pattern thereon, separately, and bonding the first and second bulks to each other. The upper circuit pattern may include, for example, a transistor, an upper contact plug, an upper wiring, an upper via, etc.

Hereinafter, the via 575, the second wiring 590 and the first bonding pattern 610 of the first bulk will be described.

Seventh to ninth insulating interlayer 570, 580 and 605 may be sequentially stacked on the sixth insulating interlayer and the first wiring 560 of the first bulk. Each of the seventh to ninth insulating interlayers 570, 580 and 605 may include, for example, an oxide such as silicon oxide.

The via 575 may extend through the seventh insulating interlayer 570 to contact an upper surface of the first wiring 560. The second wiring 590 may extend through the eighth insulating interlayer 580 to contact an upper surface of the via 575. Each of the via 575 and the second wiring 590 may include a conductive material, for example, a metal, a metal nitride, a metal silicide, polysilicon doped with impurities, etc.

The first bonding pattern 610 may extend through the ninth insulating interlayer 605 to contact an upper surface of the second wiring 590. The first bonding pattern 610 is shown to include a lower portion and an upper portion with a larger width than that of the lower portion, but the present disclosure is not limited thereto.

The first bonding pattern 610 may include, for example, a low-resistance material such as copper, aluminum, etc.

Hereinafter, the second substrate 700, the transistor, an upper contact plug 770, first to third wirings 780, 800 and 820 and first and second upper vias 790 and 810 of the second bulk will be described. For convenience, the following description may be based on a state in which top and bottom of the structures of the second bulk are inverted.

The second substrate 700 may include a field region on which a second isolation pattern 710 is formed and a second active region 701 on which no second isolation pattern is formed. The second isolation pattern 710 may include an oxide, e.g., silicon oxide.

The transistor may include an upper gate structure 750 on the second substrate 700 and third and fourth impurity regions 702 and 703 at upper portions of the second active region 701 adjacent to the upper gate structure 750 serving as source/drain regions. The upper gate structure 750 may include an upper gate insulation pattern 720 and an upper gate electrode 730 sequentially stacked on the second substrate 700.

A first upper insulating interlayer 760 may be formed on the second substrate 700 to cover the transistors, and the upper contact plug 770 extending through the first upper insulating interlayer 760 to contact the third impurity region 702 may be formed. The first upper insulating interlayer 760 may include, for example, an oxide such as silicon oxide.

The first upper wiring 780 may be formed on the first upper insulating interlayer 760 to contact an upper surface of the upper contact plug 770. The first upper via 790, the second upper wiring 800, the second upper via 810, and the third upper wiring 820 may be sequentially stacked on the first upper wiring 780.

The second upper insulating interlayer 830 may be formed on the first upper insulating interlayer 760 to cover the first to third wirings 780, 800, and 820 and the first and second upper vias 790 and 710. The second upper insulating interlayer 830 may include, for example, an oxide, such as silicon oxide.

The second bonding pattern 850 may be formed on the second upper insulating interlayer 830 to contact an upper surface of the third upper wiring 820. The second bonding pattern 850 is shown to include a lower portion and an upper portion with a larger width than that of the lower portion, but the concept of the present invention is not limited thereto. The second bonding pattern 850 may include, for example, a low-resistance material such as copper, aluminum, etc.

The third upper insulating interlayer 840 may be formed on the second upper insulating interlayer 820 to cover the second bonding pattern 850. The third upper insulating interlayer 840 may include, for example, an oxide, such as silicon oxide.

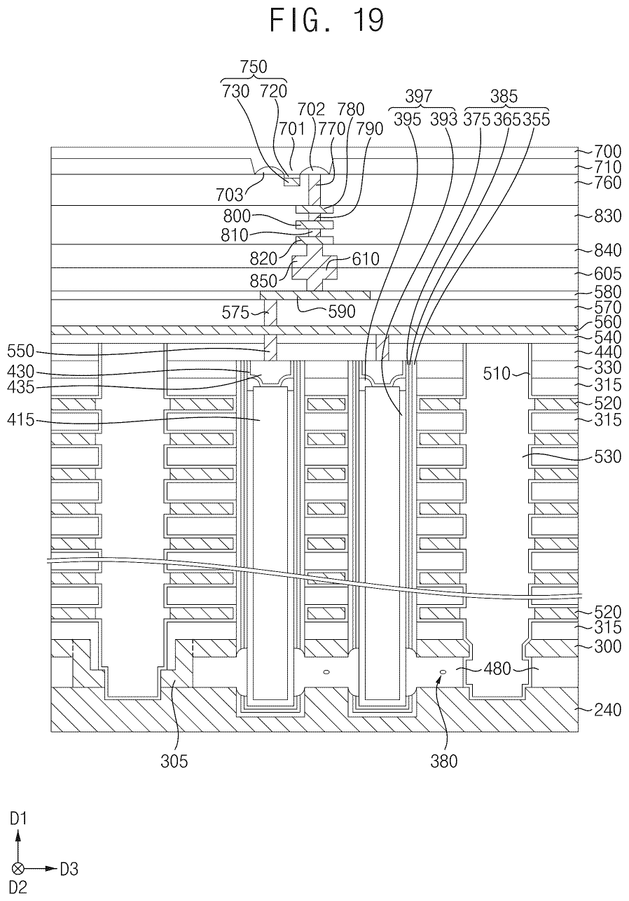

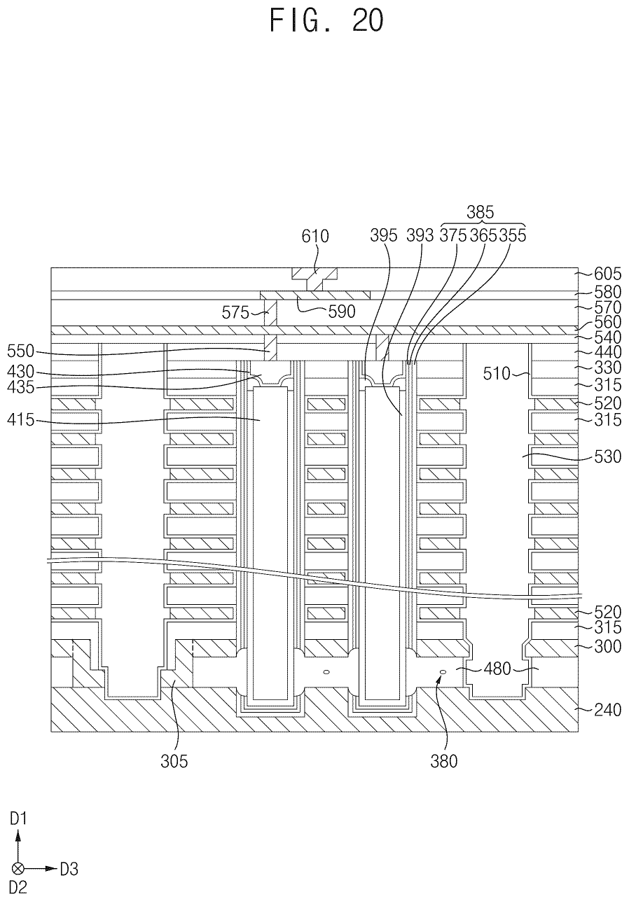

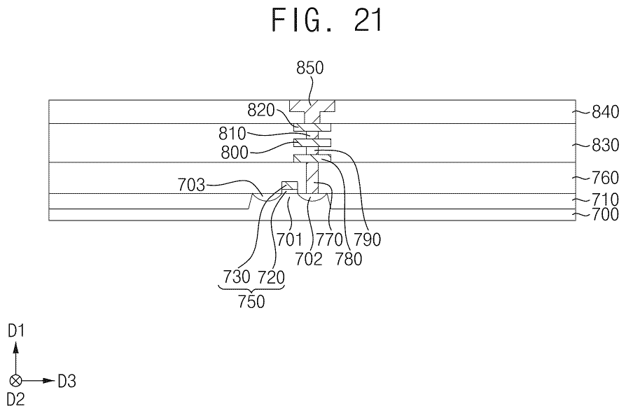

In FIGS. 20 and 21 together with FIG. 19, an upper surface of the first bonding pattern 610 of the first bulk and an upper surface of the second bonding pattern 850 of the second bulk may contact each other.

FIGS. 20 to 21 are cross-sectional views illustrating an example of a method of forming a semiconductor device in accordance with some implementations. This method may include processes substantially the same as or similar to those illustrated with reference to FIGS. 1 to 15, and thus repeated explanations thereof are omitted herein.

In FIG. 20, unlike the processes illustrated with reference to FIG. 2, the lower circuit pattern may not be formed. Thereafter, processes substantially the same as or similar to those described with reference to FIGS. 3 to 15 may be performed.

In FIG. 20, a seventh insulating interlayer 570 may be formed on the sixth insulating interlayer and the first wiring 560 of the first bulk, and a via 575 extending through the seventh insulating interlayer 570 may be formed to contact an upper surface of the first wiring 560.

An eighth insulating interlayer 580 may be formed on the seventh insulating interlayer 570 and the via 575, and a second wiring 590 extending through the eighth insulating interlayer 580 may be formed to contact an upper surface of the via 575.

A ninth insulating interlayer 605 may be formed on the eighth insulating interlayer 580 and the second wiring 590, and a first bonding pattern 610 extending through the ninth insulating interlayer 605 may be formed to contact an upper surface of the second wiring 590.

In some implementations, the first bonding pattern 610 may be formed by a dual damascene process, and may be formed to include a lower portion and an upper portion having a width greater than that of the lower portion. In some implementations, the first bonding pattern 610 may be formed by a single damascene process.

In FIG. 21, an upper circuit pattern may be formed on a second substrate 700 including a second active region 701 defined by a second isolation pattern 710. The upper circuit patterns may include, for example, a transistor, an upper contact plug, an upper wiring, an upper via, etc.

The transistor may include an upper gate structure 750 on the second substrate 700 and third and fourth impurity regions 702 and 703 at upper portions of the second active region 701 adjacent to the upper gate structure 750 serving as source/drain regions. The upper gate structure 750 may include an upper gate insulation pattern 720 and an upper gate electrode 730 sequentially stacked on the second substrate 700.

A first upper insulating interlayer 760 may be formed on the second substrate 700 to cover the transistors, and an upper contact plug 770 extending through the first upper insulating interlayer 760 to contact the third impurity region 702 may be formed.

A first upper wiring 780 may be formed on the first upper insulating interlayer 760 to contact an upper surface of the upper contact plug 770. A first upper via 790, a second upper wiring 800, a second upper via 810, and a third upper wiring 820 may be sequentially formed on the first upper wiring 780.

A second upper insulating interlayer 830 may be formed on the first upper insulating interlayer 760 to cover the first to third wirings 780, 800, and 820 and the first and second upper vias 790 and 710.

A third upper insulating interlayer 840 may formed on the second upper insulating interlayer 830 and the third upper wiring 820, and a second bonding pattern 850 extending through the third upper insulating interlayer 840 may be formed to contact an upper surface of the third upper wiring 820.

In some implementations, the second bonding pattern 850 may be formed at a position corresponding to the first bonding pattern 610.

In some implementations, the second bonding pattern 850 may be formed by a dual damascene process, and thus may be formed to include a lower portion and an upper portion having a larger width than that of the lower portion. In some implementations, the second bonding pattern 850 may be formed by a single damascene process.

Hereinafter, the first substrate 100 and components thereon may be together referred to as a first bulk, and the second substrate 700 and components thereon may be together referred to as a second bulk.

In FIG. 19, the second bulk may be turned over, and an upper surface of the second bonding pattern 850 of the second bulk may be bonded with an upper surface of the first bonding pattern 610 of the first bulk.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a plurality of gate electrodes on a substrate, the plurality of gate electrodes being spaced apart from each other in a vertical direction substantially perpendicular to an upper surface of the substrate; and
a memory channel structure extending through the plurality of gate electrodes in the vertical direction on the substrate,
wherein the memory channel structure includes:
a filling pattern extending in the vertical direction;
a channel structure on a sidewall of the filling pattern and an edge portion of an upper surface of the filling pattern, the channel structure comprising a single crystalline silicon or a quasi-single crystalline silicon;
a capping pattern on a central portion of the upper surface of the filling pattern and an upper surface of the channel structure, the capping pattern comprising polycrystalline silicon; and
a charge storage structure on an outer sidewall of the channel structure and a sidewall of the capping pattern.

2. The semiconductor device of claim 1, wherein an upper portion of the channel structure comprises a silicide of a metal.

3. The semiconductor device of claim 2, wherein the metal comprises at least one of nickel, cobalt, or platinum.

4. The semiconductor device of claim 1, wherein the channel structure further comprises at least one of oxygen, carbon, or nitrogen.

5. The semiconductor device of claim 1,
wherein an orientation of the single crystalline silicon or the quasi-single crystalline silicon of the channel structure is constant,
wherein an orientation of the polycrystalline silicon of the capping pattern is random.

6. The semiconductor device of claim 1,
wherein the memory channel structure further includes a seed pattern disposed between the channel structure and the capping pattern, and
wherein the seed pattern comprises polysilicon doped with at least one of oxygen, carbon, or nitrogen.

7. The semiconductor device of claim 6, wherein the seed pattern covers the sidewall of the capping pattern.

8. A semiconductor device comprising:
a plurality of gate electrodes on a substrate, the plurality of gate electrodes being spaced apart from each other in a vertical direction substantially perpendicular to an upper surface of the substrate; and
a memory channel structure extending through the plurality of gate electrodes in the vertical direction on the substrate,
wherein the memory channel structure includes:
a filling pattern extending in the vertical direction;
a channel structure comprising:
a first channel covering a sidewall of the filling pattern, the first channel comprising a single crystalline silicon or a quasi-single crystalline silicon; and
a second channel on and contacting the first channel, the second channel having a shape of a ring covering an edge portion of an upper surface of the filling pattern, and the second channel comprising a metal silicide; and
a charge storage structure on a sidewall of the channel structure.

9. The semiconductor device of claim 8, wherein an upper surface of the first channel is lower than the upper surface of the filling pattern.

10. The semiconductor device of claim 8, wherein an inner diameter of the second channel is smaller than an inner diameter of the first channel.

11. The semiconductor device of claim 8, wherein an inner diameter of the second channel increases in the vertical direction away from the upper surface of the substrate.

12. The semiconductor device of claim 8,
wherein the memory channel structure further includes a capping pattern on a central portion of the upper surface of the filling pattern and an upper surface of the channel structure, and
wherein the capping pattern comprises polycrystalline silicon.

13. The semiconductor device of claim 12, wherein the second channel comprises a single crystalline silicon or a quasi-single crystalline silicon.

14. The semiconductor device of claim 13,
wherein an orientation of the single crystalline silicon or the quasi-single crystalline silicon of each of the first channel and the second channel is constant, and
wherein an orientation of the polycrystalline silicon of the capping pattern is random.

15. The semiconductor device of claim 12,
wherein the memory channel structure further includes a seed pattern disposed between the channel structure and the capping pattern, and
wherein the seed pattern comprising polysilicon doped with at least one of oxygen, carbon, or nitrogen.

16. The semiconductor device of claim 15, wherein the seed pattern covers a sidewall of the capping pattern.

17. A semiconductor device comprising:
a plurality of gate electrodes on a substrate, the plurality of gate electrodes being spaced apart from each other in a vertical direction substantially perpendicular to an upper surface of the substrate; and
a memory channel structure extending through the plurality of gate electrodes in the vertical direction on the substrate,
wherein the memory channel structure comprises:
a filling pattern extending in the vertical direction;
a channel structure comprising:
a first channel covering a lower surface of the filling pattern, the first channel comprising polycrystalline silicon;
a second channel on the first channel, the second channel covering a sidewall of the filling pattern, and the first channel comprising a single crystalline silicon or a quasi-single crystalline silicon; and
a third channel on the second channel, the third channel covering an edge portion of an upper surface of the filling pattern, and the third channel comprising a metal silicide; and
a charge storage structure on a sidewall of the channel structure.

18. The semiconductor device of claim 17,
wherein an upper surface of the second channel is lower than the upper surface of the filling pattern, and
wherein the third channel covers an uppermost portion of the sidewall of the filling pattern.

19. The semiconductor device of claim 17, wherein the first channel covers a lower portion of the sidewall of the filling pattern.

20. The semiconductor device of claim 17, wherein the channel structure further comprises at least one of oxygen, carbon, or nitrogen.
